(19) United States
(12) Patent Application Publication
(10) Pub. No.: US 2006/0291278 A1
(43) Pub. Date: Dec. 28, 2006

(54) Nano-Reflectors for Thin, Flat Display Devices

(75) Inventors: Andrew Tipton, Des Moines, IA (US); Arthur V. Pohm, Ames, IA (US); Carl L. Tipton, Ames, IA (US)

Correspondence Address: ANDREW TIPTON, 320 NW UPTOWN TERRACE, UNIT 1A, PORTLAND, OR, 97210, US

(73) Assignee: NANO-ELECTROCHEM, INC., Des Moines, IA (US)

(21) Appl. No.: 11/308,427

(22) Filed: Mar. 23, 2006

(30) Foreign Application Priority Data
Jun. 24, 2005 (CN) 200510035530.0

(51) Int. Cl. G11C 11/56

(52) U.S. Cl. 365/168

(57) ABSTRACT

A display device is described comprising a first transparent electrode, a second electrode, and a pixel, wherein the pixel, in-between the first electrode and the second electrode, comprises a display molecule connected to a first surface, the display molecule comprises an electron donor, a conjugated bridge and an electron acceptor.

### FIELD OF THE INVENTION

This invention relates in general to the field of thin, flat display devices comprising pixels arrayed in front of a light source or reflector. A common type of thin, flat display device is the liquid crystal display (LCD). A LCD comprises two transparent electrodes, a column of liquid crystal molecules suspended between the electrodes and two polarizing filters with perpendicular axes of polarity. Without the liquid crystals, light passing through one filter is blocked by the other. The liquid crystals change the polarization of light entering one filter allowing the light to pass through the other. With no applied bias, the liquid crystal molecules align in a helical structure. With an applied bias, the molecules of the liquid crystal align themselves parallel to the electric field, limiting the rotation of entering light. The more the helical structure is disturbed, the more light passing through it is polarized perpendicular to the second filter and, thus, blocked.

The following factors are important when judging a LCD: resolution, viewable size, response time, viewing angle, color support, brightness, contrast ratio and aspect ratio. Shortcomings of a LCD, when compared to a cathode ray tube or plasma display, include a low contrast ratio, a long response time when the image changes and a low viewing angle reducing the number of people who can view the same image.

A need exists to improve thin, flat display devices. Such a device is the subject of the present invention. The device of the present invention builds on past work on nanotechnology, self-assembled monolayers and chromophores for electro-optic and photorefractive applications.

### SUMMARY OF THE INVENTION

An object of the present invention is to provide a thin, flat display device comprising pixels aligned in front of an electromagnetic radiation source or reflector. The display requires modest applied voltages and yields high reflectivity. A further object of the present invention is to provide a method to make such a display device where the reflectivity can be turned on and off.

In one embodiment, pixels, each comprising a reflective first surface and a display molecule are dispersed in an insulating dielectric liquid. In another embodiment, each pixel further comprises a non-reflective second surface. The diameter of each reflecting surface, preferably 0.01 to 1.0 microns for visible radiation, is chosen to optimize reflection for the radiation frequency under consideration. When a bias is applied across the dielectric fluid, the pixels form induced dipoles that align with the field and greatly enhance the reflection. Due to the dielectric asymmetry, the molecules form induced dipoles that align. Under a bias, the first surface reflects incoming radiation. When the bias is reversed, the pixel realigns in the dielectric fluid and the second surface absorbs incoming radiation. Thus, a light switch is formed. The surfaces can be treated to preferentially reflect certain colors. A similar phenomenon occurs with molecular rectifiers in a very slightly conducting solvent or solution. The rectifier can be the basis for a similar switch.

The invention is useful for stealth applications where an object such as a ship or aircraft, coated with display devices, is alternatively visible and invisible to incoming radiation.

The display molecule, in its simplest form, comprises an electron donor, an electron acceptor, a first connector between the electron donor and first surface and a conjugated bridge between the electron donor and electron acceptor. A preferred display structure further comprises a second surface and a second connector between the electron acceptor and the second surface. The positions of the electron donor and acceptor are interchangeable.

Preferred electron donors include, but are not limited to, amino, phosphino and thioether groups and combinations thereof. Preferred electron acceptors include, but are not limited to, nitro, carbonyl, oxo, thioxo, sulfonyl, malononitrile, isoxazolone, cyano, dicyano, polycyano, nitrile, dicarbonitrile, polycarbonitrile and combinations thereof. The conjugated bridge comprises one or more double bonds that alternate with single bonds in an unsaturated compound. Among the many elements that may be present in the double bond, carbon, nitrogen, oxygen and sulfur are the most preferred. The π electrons in the conjugated bridge are delocalized across the length of the bridge. Preferred conjugated bridges include, but are not limited to, alkenes, alkynes, dienes, trienes, polyenes, diazenes, 1,2-diphenylethene, 1,2-diphenyldiazene, styrene, hexa-1,3,5-trienylbenzene, 1,4-di(thiophen-2-yl)buta-1,3-diene and combinations thereof.

Preferably, the display molecule should be long. In one embodiment, the display molecules are stacked in more than one layer, to yield a favorable length to width ratio, before etching the pixel. For example, a first (mono) layer of display molecules is bonded to the first surface. A second layer, such as gold, is placed onto the first layer. A third (mono) layer of display molecules is bonded to the second layer and so on until the second surface is placed on top of a layer to terminate the stacking.

A connector comprises an atom or atoms that join the first surface to the electron donor (first connector) and, optionally, the electron acceptor to the second surface (second connector) selected from the group consisting of boron, carbon, nitrogen, oxygen, silicon, gallium, arsenic, phosphorus, sulfur, selenium, tellerium and combinations thereof. The positions of the electron donor and acceptor are interchangeable. A preferred connector is selected from the group consisting of silicon, sulfur, selenium and combinations thereof.

Preferred groups that contain a connector are selected from the group consisting of —XC(R¹)(R²)—, —(X¹)(X²)C(R¹)Q- and —(X¹)(X²)C(R¹)N(R²)Q- wherein X¹ and X² are the same or different and are selected from the group consisting of silicon, sulfur and selenium, where R¹ and R² are the same or different and are selected from the group consisting of hydrogen, halogens, C₁-C₅ alkyl and C₁-C₅ haloalkyl and where Q is selected from the group consisting of hydrogen, halogens, C₁-C₃₀ alkyl and C₁-C₃₀ haloalkyl.

The first and second surfaces are chosen independently from the group consisting of reflective and non-reflective surfaces. Reflective surfaces include, but are not limited to, metal and semiconductor surfaces. Preferred reflective surfaces are selected from the group consisting of gold, silver, copper, palladium, platinum, silicon, carbon, gallium arsenide and combinations thereof. Preferred non-reflective surfaces are non-metal surfaces including carbon surfaces. The surfaces are flat or non-flat.

In one embodiment, the display molecule further comprises a first insulator between the first connector and the electron donor. In another embodiment, the display molecule further comprises a second insulator between the second surface and the electron acceptor.

The first insulator and the second insulator are the same or different and are selected from any insulating groups. Preferred insulators include, but are not limited to, substituted or unsubstituted alkyl, haloalkyl, ether, silane, siloxane and phosphazene groups and combinations thereof. Particularly preferred insulators are selected from the group consisting of alkyl and fluoroalkyl groups and combinations thereof.

The preferred first surface is Au(111). A Au(111) surface is preferably obtained from the evaporation of gold onto a flat support. Flat supports include, but are not limited to, glass, plastic, semiconductor and metal surfaces.

Display molecules containing thiol groups bond to the Au(111) surface from solution and create a dense monolayer with the display molecules pointing outward from the Au(111) surface. In another embodiment, a second surface is attached to the other end of the monolayer. The resulting pixel is divided into smaller pixels via reactive ion, plasma and chemical etching or other means common to the semiconductor industry.

Preferred transparent first electrodes generally comprise metal oxides, metal selenides and thin coatings of metal. More preferred transparent first electrodes are selected from the group consisting of indium tin oxide, zinc doped indium oxide, nickel hydroxide, tungsten trioxide, cadmium tin oxide (Cd₂SnO₄), copper indium gallium selenide (CuIn₁₋ₓGaₓSe₂), tin oxide, fluorine doped tin oxide, antimony doped tin oxide, aluminum doped zinc oxide, fluorine doped zinc oxide, zinc oxide, thin coatings of metal and combinations thereof.

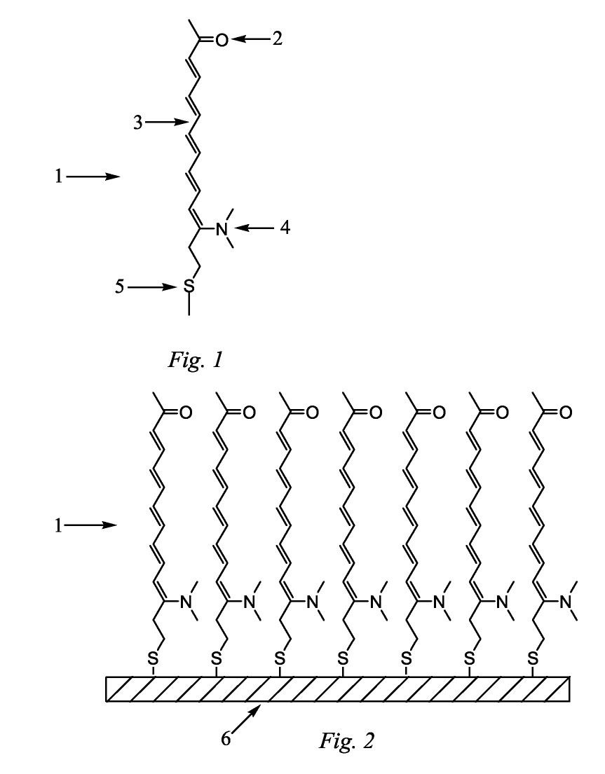

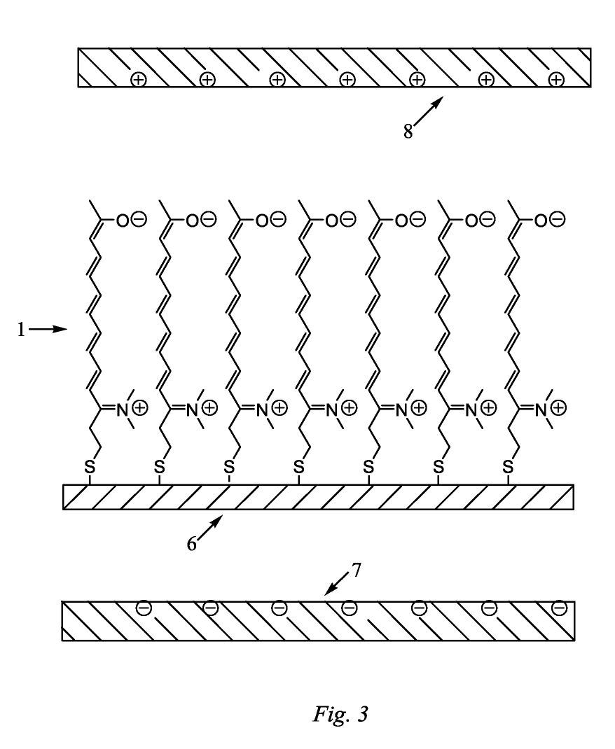

FIG. 1 illustrates the components comprising a display molecule 1: a connector 5, an electron donor 4, a conjugated bridge 3 and an electron acceptor 2. FIG. 2 illustrates a two-dimensional array of display molecules 1. The connectors 5 to the first surface 6 are thiol linkages. The array of display molecules 1 is typically three-dimensional. FIG. 3 illustrates the induced dipoles of the display molecules 1 under a bias that cause the pixels to align with the applied field and provide a reflecting or non-reflecting surface. The first transparent electrode 7 and second electrode 8 are shown.

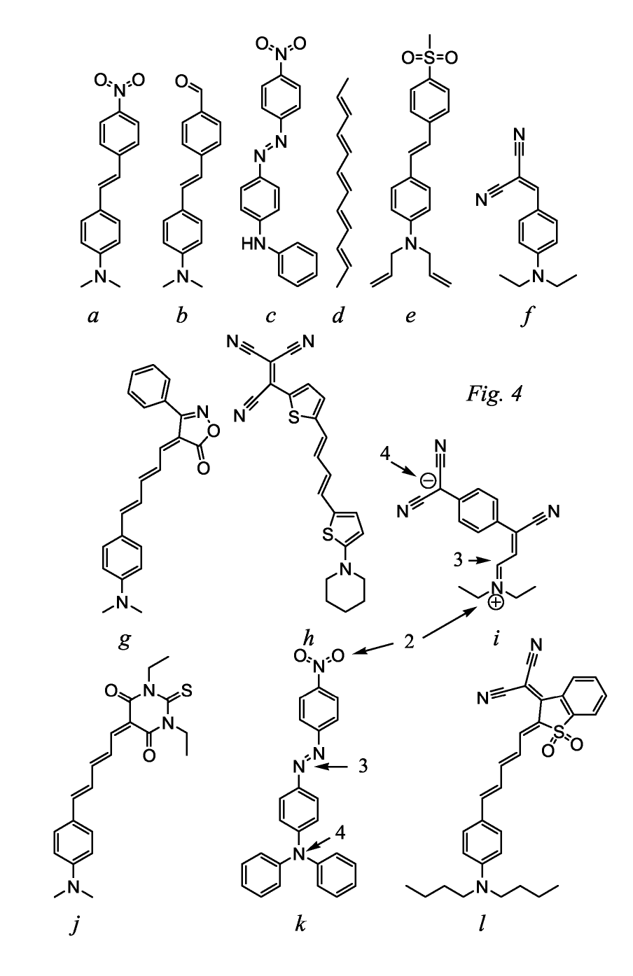

FIGS. 4(a) to (l) illustrate preferred electron donor 4, conjugated bridge 3, electron acceptor 2 combinations for display molecules: N,N-dimethyl-4-(4-nitrostyryl)aniline (a), 4-(4-(dimethylamino) styryl)benzaldehyde (b), 4-((4-nitrophenyl)diazenyl)-N-phenylaniline (c), dodeca-2,4,6,8,10-pentaene (d), N,N-diallyl-4-(4-(methylsulfonyl)styryl)aniline (e), 2-(4-(diethylamino)benzylidene)malononitrile (f), 4-(5-(4-(dimethylamino)phenyl)penta-2,4-dienylidene)-3-phenylisoxazol-5-one (g), 2-(5-(4-(5-(piperidin-1-yl)thiophen-2-yl)buta-1,3-dienyl)thiophen-2-yl)ethene-1,1,2-tricarbonitrile (h), dicyano(4-(1-cyano-3-(diethyliminio)prop-1-enyl)phenyl)methanide (i), 5-(5-(4-(dimethylamino)phenyl)penta-2,4-dienylidene)-1,3-diethyl-2-thioxodihydropyrimidine-4,6-dione (j), 4-((4-nitrophenyl)diazenyl)-N,N-diphenylaniline (k) and unknown name (l). 7(a) is atypical as it is already quite polarized without an external bias. Compare this to the more typical 7(k).

Other preferred molecules with electron donors 4 and electron acceptors 2 separated by conjugated bridges 3 (also known as non-linear optical (NLO) chromophores) include, but are not limited to, (2,6-Dimethyl-4H-pyran-4-ylidene)malononitrile, (S)-(−)-1-(4-Nitrophenyl)-2-pyrrolidinemethanol, [4-[Bis(2-hydroxyethyl)amino]phenyl]-1,1,2-ethylenetricarbonitrile, 1-Docosyl-4-(4-hydroxystyryl)pyridinium bromide, 2-(Dimethylamino)vinyl-1-nitronaphthalene, 2,3,5,6-Tetrafluoro-7,7,8,8-tetracyanoquinodimethane, 4-[4-(Dimethylamino)styryl]-1-methylpyridinium p-toluenesulfonate, 2-[[5-(Dibutylamino)-2-thienyl]methylene]-1H-indene-1,3(2H)-di one, 2-[4-((4-(Bis(2-hydroxyethyl)amino]phenyl)(cyano)methylene]-2,5-cyclohexadien-1-ylidene]malonitrile, 2-[4-(Dimethylamino)styryl]pyridine, 2-[Ethyl[4-[2-(4-nitrophenyl)ethenyl]phenyl]amino]ethanol, 2-Amino-3-nitropyridine, 2-Amino-5-nitropyridine, 2-Aminofluorene, 2-Chloro-3,5-dinitropyridine, 2-Chloro-4-nitroaniline, 2-Methyl-4-nitroaniline, 2-Nitroaniline, 3-[(4-Nitrophenyl)azo]-9H-carbazole-9-ethanol, 3-Methyl-4-nitropyridine N-oxide, 3-Nitroaniline, 4-(Dibenzylamino)benzaldehyde-N,N-diphenylhydrazone, 4-[4-(Dimethylamino)styryl]-1-docosylpyridinium bromide, 4-[4-(Dimethylamino)styryl]pyridine, 4-Dimethylamino-4′-nitrostilbene, 4-Nitroaniline, 5-Nitroindole, 5-Nitrouracil, 7,7,8,8-Tetracyanoquinodimethane, 9-Ethyl-3-carbazolecarboxaldehyde-N-methyl-N-phenylhydrazone, Disperse Orange 25, Disperse Orange 3, Disperse Red 1, Disperse Red 13, Disperse Red 19, Disperse yellow 7, Ethyl 4-(dimethylamino)benzoate, Gentian Violet, N-(2,4-Dinitrophenyl)-L-alanine methyl ester, N,N-Dimethyl-N′-[(5-nitro-2-thienyl)methylene]-1,4-phenylenediamine, N-[3-Cyano-3-[4-(dicyanomethyl)phenyl]-2-propenylidene]-N-ethyl-ethaniminium inner salt, Nile Blue A, N-Methyl-4-nitroaniline, trans-4-[4-(Dimethylamino)styryl]-1-methylpyridinium iodide and trans-4-[4-(Dimethylamino)styryl]-1-methylpyridinium p-toluenesulfonate.

A display molecule 1 may have more than one connector 5 to a surface and more than one electron donor 4, electron acceptor 2 and conjugated bridge 3. The array of display molecules 1 may comprise a mixture of display molecules 1. An advantage to a mixture of display molecules 1 is to lower electron donor-electron donor 4 and electron acceptor-electron acceptor 2 intermolecular repulsions. The lengths of the insulators and conjugated bridges 3 are adjustable. The display molecules 1 are often non-perpendicular to the first surface 6 as they often tilt to maximize van der Waals forces between adjacent molecules.

The pixels are made by placing the first surface in contact with a solution containing the display molecule 1 until a monolayer of the display molecule 1 bonds to the surface, rinsing the first surface 6 and monolayer with solvent to remove excess display molecule 1 followed by drying. The concentration of the display molecule 1 solution is preferably between 0.01 mM and 100 mM. The solubility of each display molecule 1 varies, but a preferred solution is 0.5 mM display molecule in 0.1 M NaOH water/ethanol (1:1, v/v). The first surface 6 is preferably in contact with the display molecule 1 solution for approximately one minute to approximately 96 hours, and preferably from approximately 10 hours to approximately 25 hours, and most preferably from approximately 12 hours to approximately 17 hours. In one embodiment, the time the first electrode is in contact with the non-linear dielectric molecule solution is approximately 15 hours. The resulting pixel is preferably rinsed with solvent such as water, then ethanol, and dried with an inert gas such as nitrogen, helium, argon, neon, and combinations thereof. The second surface is preferably deposited by vapor deposition. The pixel is cut into smaller pixels via reactive ion, plasma and chemical etching or other means common to the semiconductor industry.

In another embodiment, the display molecule is attached to a first electrode that is already of the size required for the pixel. The solution of the dielectric molecule is exposed to an array of small first electrodes. The first electrodes can be on a substrate that can be later removed, such as by dissolving the substrate from under the electrodes. The second electrode is still deposited on the array of display molecules, but little or no etching is needed to separate the structure into pixels as the pixels are already discrete.

In another embodiment, the display molecule 1 is brought into contact with the first surface 6 from the gas phase. The pressure of the gas phase is preferably between approximately 10⁻⁶ mbar and approximately 400 mbar. The process temperature is preferably between approximately 15° C. and 200° C. The deposition time ranges from approximately 10 seconds to approximately 48 hours.

1. A display device comprising:
a transparent first electrode;
a second electrode opposed to the first electrode; and
a pixel, the pixel between the first electrode and the second electrode, wherein the pixel comprises a display molecule with asymmetric dielectric properties connected to a first surface, wherein the display molecule comprises an electron donor and an electron acceptor separated by a conjugated bridge, and the electron donor and electron acceptor are separated by more than four atoms.

2. The display device of claim 1 further comprising a plurality of pixels.

3. The display device of claim 2 further comprising a mixture of display molecules.

4. The display device of claim 1, wherein the display molecule further comprises a first insulator.

5. The display device of claim 1, wherein the display molecule further comprises a second insulator.

6. The display device of claim 4 wherein the first and second insulators are independently selected from the group consisting of substituted and unsubstituted alkyl, haloalkyl, ether, silane, siloxane and phosphazene groups and combinations thereof.

7. The display device of claim 1 wherein the conjugated bridge is selected from the group consisting of alkenes, dienes, trienes, polyenes, 1,2-diphenylethene, 1,2-diphenyldiazene, styrene, hexa-1,3,5-trienylbenzene and 1,4-di(thiophen-2-yl)buta-1,3-diene and combinations thereof.

8. The display device of claim 1, wherein the connector is selected from the group consisting of boron, carbon, nitrogen, oxygen, silicon, gallium, arsenic, phosphorus, sulfur, selenium, tellurium and combinations thereof.

9. The display device of claim 1 wherein the electron donor is selected from the group consisting of amino, phosphino, thioether groups and combinations thereof.

10. The display device of claim 1 wherein the electron acceptor is selected from the group consisting of nitro, carbonyl, oxo, thioxo, sulfonyl, malononitrile, isoxazolone, cyano, dicyano, tricyano, tetracycano, nitrile, dicarbonitrile, tricarbonitrile and thioxodihydropyrimidinedione groups and combinations thereof.

11. The display device of claim 1 wherein the electron donor is an amino group, the electron acceptor is selected from the group consisting of nitro, carbonyl and cyano groups and the conjugated bridge is selected from the group consisting of alkenes, dienes, trienes and polyenes.

12. The display device of claim 1 wherein the pixel size is optimized for the wavelength of radiation reflected.

13. A method for making a display device comprising:
bonding a first layer of display molecules to a first surface forming a pixel; and
placing the pixel between a first transparent electrode and a second electrode.

14. The method of claim 13 further comprising:
applying a second surface on top of the first layer of display molecules.

15. The method of claim 13 further comprising:
applying a second layer on top of the first layer wherein the second layer comprises a material that bonds to display molecules; and
depositing a third layer to the second layer wherein the third layer comprises a monolayer of display molecules.

16. The method of claim 15 further comprising:
repeating the applying and depositing steps a number of times to build a mulitlayer pixel.

17. The method of claim 12 further comprising:
rinsing the first surface and monolayer with solvent to remove excess display molecules;
and drying the first electrode and monolayer.

18. A display device comprising:
a transparent first electrode;
a second electrode opposed to the first electrode; and
a pixel, the pixel between the first electrode and the second electrode, wherein the pixel comprises a display molecule connected to a gold first surface, wherein the display molecule comprises an electron donor and an electron acceptor separated by a conjugated bridge, wherein the electron donor and electron acceptor are separated by more than four atoms and the electron donor comprises an amino group.
